(19) United States
(12) Patent Application Publication
(10) Pub. No.: US 2026/0282556 A1
(43) Pub. Date: Sep. 17, 2026

(54) ASYMMETRIC GATE SPACING IN SEMICONDUCTOR DEVICES

(71) Applicant: Taiwan Semiconductor Manufacturing Company, Ltd., Hsin-Chu (TW)

(72) Inventors: Jui-Wen Chang, Hsinchu (TW); Feng-Ming Chang, Hsinchu County (TW); Yi-Feng Ting, Taipei City (TW); Jui-Lin Chen, Taipei City (TW); Ping-Wei Wang, Hsin-Chu (TW)

(21) Appl. No.: 19/253,317

(22) Filed: Jun. 27, 2025

Related U.S. Application Data
(60) Provisional application No. 63/772,012, filed on Mar. 14, 2025.

(51) Int. Cl. H10D 89/10; H10D 64/27; H10D 84/01

(52) U.S. Cl. CPC H10D 89/10; H10D 64/518; H10D 84/0153

(57) ABSTRACT

A semiconductor device includes first, second, third, fourth, and fifth active regions extending lengthwise along a first direction. The first and fifth active regions extend completely across a first cell and an adjacent second cell. The second, third, and fourth active regions extend partially across the first and second cells and are disposed between the first and fifth active regions along a second direction. The device includes a first gate stack engaging the first and second active regions and second and third gate stacks engaging the fourth and fifth active regions. The second gate stack extends in the second direction between the first and the third gate stacks. A spacing between the first gate stack and the second gate stack spans a first distance, a spacing between the second gate stack and the third gate stack spans a second distance, and the second distance is greater than the first distance.

### PRIORITY DATA

This application claims the benefit of U.S. Provisional Application No. 63/772,012 filed Mar. 14, 2025, the entirety of which is herein incorporated.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

One advancement is in the adoption of nanostructure designs in memory devices. However, as transistor pitch becomes smaller, the memory devices may experience reliability and performance issues. For example, the reduced pitch at smaller technology nodes may lead to reduced structural integrity, poorer epitaxial growth, and increased gate-to-gate leakage.

Therefore, although existing memory device structures and layouts have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a circuit diagram of an SRAM array, according to an embodiment of the present disclosure.

FIG. 2 illustrates a flow chart of a method 1000 to form a memory device having asymmetric gate spacings, in portion or in entirety, according to an embodiment of the present disclosure.

FIGS. 3-6 illustrate top view device layouts of an SRAM array at intermediate stages of fabrication and corresponding to the circuit diagram of FIG. 2, according to an embodiment of the present disclosure.

FIGS. 7A-7B illustrate cross-sectional views of an SRAM array cut along respective lines A-A′ and B-B′ in FIG. 6, according to an embodiment of the present disclosure.

FIGS. 8A-8B illustrate cross-sectional views of an SRAM array cut along the line A-A′ in FIG. 6, according to additional embodiments of the present disclosure.

FIGS. 9-12 illustrate top view device layouts of various SRAM arrays having asymmetric gate spacings, according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/-10% between the compared features. Note that other ranges are possible as known by those skilled in the art and may be process dependent. Further, disclosed dimensions of the different features can implicitly disclose dimension ratios between the different features.

Memory devices, such as static random access memory (SRAM) devices have become a popular storage unit for high speed communication, image processing, and system-on-chip (SOC) products. To meet the continuous demand of scaling down feature sizes while optimizing power consumption, SRAM devices have begun to adopt nanostructure transistors such as gate-all-around (GAA) transistors. However, due to the inherent layout of SRAM cell structures, metal gates may land on regions directly adjacent to edges of p-type active regions. These p-type active regions form pull-up transistors of the SRAM device. The metal gates'close proximity to these active region edges may result in uneven landings caused by slope changes in surface topography. This in turn causes the respective metal gates to bend, causing the space between adjacent metal gates at the Vcc node (the source terminal of adjacent pull-up transistors) to decrease. This results in a smaller spacing to form source epitaxial features at the Vcc node, which may lead to performance degradation. In some GAA designs, this smaller spacing may cause oxide residue at the bottom of the source/drain trench when forming disposable oxide interposers. The oxide residue causes poor epitaxial growth and may further lead to gate-to-gate shorting during the metal gate replacement of the disposable oxide interposers.

For this and other reasons, the present disclosure provides SRAM layouts with asymmetric gate spacings. The asymmetric gate spacings increase the distance between adjacent metal gates at the source/drains for Vcc nodes by proportionally decreasing the distance between adjacent metal gates at adjacent source/drains. By increasing the spacing at the Vcc source/drain, issues caused by gate bending are mitigated, which helps prevent poor epitaxial growth and gate-to-gate leakage. Various gate jogs may be formed to achieve asymmetric gate spacing. These gate jogs are large enough to prevent gate-to-gate leakage yet small enough to form continuous gates without breakage. The present disclosure further introduces gate extensions at regions adjacent to the edges of active regions to further mitigate gate bending and smooth out gate landing. Through various combinations of gate asymmetry, gate jog, and gate extensions, SRAM process window is improved when forming epitaxial features, such as when forming undoped L0 epitaxial features, at Vcc of p-type active regions.

Embodiments shown in the present disclosure are implemented with Gate-All-Around (GAA) field effect transistors (FETs), but the present disclosure is not limited thereto. GAA FETs refer to transistors having gate stacks (gate electrodes and gate dielectric layers) surrounding transistor channels, such as vertically-stacked gate-all-around horizontal nanowire or nanosheet MOSFET devices. Those of ordinary skill in the art should appreciate that they may readily use the present disclosure as a basis for designing or modifying other structures for carrying out the same purposes and/or achieving the same advantages of the embodiments introduced herein.

Embodiments shown in the present disclosure are implanted in memory devices, such as SRAM devices in SRAM cell layouts. However, the present disclosure is not limited thereto. The present disclosure may be generally applicable to all semiconductor devices susceptible to gate bending resulting from uneven gate landing, which may occur, for example, when a gate is placed in close proximity to an edge of an active region. Therefore, those of ordinary skill in the art should appreciate that they may readily use the present disclosure as a basis for designing or modifying other semiconductor devices, such as logic devices or other types of memory devices in cell layouts that differ from the examples illustrated. For example, in further embodiments, the asymmetric gate spacings may be applied in logic cells over n-type active regions or p-type active regions.

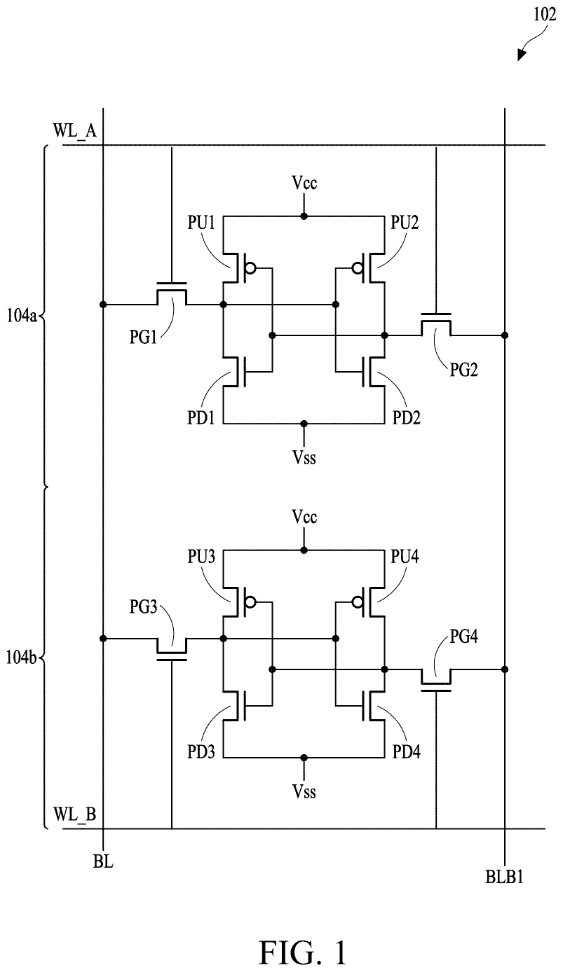

FIG. 1 illustrates a circuit diagram of a static-random-access memory (SRAM) array as part of a memory device 102, according to an embodiment of the present disclosure. The circuit diagram corresponds to an SRAM array of two memory cells 104 (or SRAM cells 104) in a memory cell area of the memory device 102. The memory cells 104 are labeled SRAM cell 104a and SRAM cell 104b. Each of the SRAM cells 104a and 104b is formed of six transistors (two pull-down transistors, two pull-up transistors, and two pass-gate transistors). Each transistor is defined by a source, a drain, and a gate. Each SRAM cell 104 stores a bit of memory through the pull-down and pull-up transistors, and the SRAM cells are addressed by word lines and bit lines through the pass-gate transistors.

The SRAM cell 104a includes pull-up transistors PU1 and PU2, pull-down transistors PD1 and PD2, and pass gate transistors PG1 and PG2. The sources of PU1 and PU2 are coupled together and connected to high voltage Vcc. The sources of PD1 and PD2 are coupled together and connected to low source voltage Vss or ground. The gates of PU1 and PD1 are coupled together and connected to the common drains of PU2, PD2 and PG2. The gates of PU2 and PD2 are coupled together and connected to the common drains of PU1, PD1, and PG1. PU1, PU2, PD1, and PD2 form a first set of cross coupled inverters to store a data bit. The source of PG1 is connected to a first bit line BL1 and the source of PG2 is connected to a first bit line bar BLB1. The gates of PG1 and PG2 are connected to a first word line WL_A.

The SRAM cell 104b includes pull-up transistors PU3 and PU4, pull-down transistors PD3 and PD4, and pass gate transistors PG3 and PG4. The sources of PU3 and PU4 are coupled together and connected to high voltage Vcc. The sources of PD3 and PD4 are coupled together and connected to low voltage Vss or ground. The gates of PU3 and PD3 are coupled together and connected to the common drains of PU4, PD4 and PG4. The gates of PU4 and PD4 are coupled together and connected to the common drains of PU3, PD3, and PG3. PU3, PU4, PD3, and PD4 form a second set of cross coupled inverters to store a data bit. The source of PG3 is connected to the same first bit line BL1 and the source of PG4 is connected to the same first bit line bar BLB1. The gates of PG3 and PG4 are connected to a second word line WL_B.

Note that FIG. 1 shows an example embodiment of an SRAM array, but other configurations may be possible. For example, in other embodiments, source and drain nodes of the different pull-up and pull-down transistors may be flipped. Further, the Vcc and Vss nodes may also be flipped. In other words, in some embodiments, high voltage Vcc may connect to source or to drain in any of the pull-up and pull-down transistors of the SRAM array. And in other embodiments, low voltage Vss or ground may connect to source or to drain in any of the pull-up and pull-down transistors of the SRAM array. As such, electrical connections to Vcc and to Vss may be referred to as power lines, power signal lines, or power line connections that provide routing to power pull-up and pull-down transistors in the memory device.

The memory device 102 may be integrated with logic components. For example, the memory device 102 may also include peripheral logic circuits adjacent to the memory cells 104 for implementing various functions such as write and/or read address decoder, word/bit selector, data drivers, memory self-testing, etc. The logic circuits may include logic cell areas, which may contain arrays of standard logic cells for implementing input/output (I/O) blocks. Each of the memory and logic circuits may be implemented with various PMOS and NMOS transistors such as planar transistors, FinFET, gate-all-around (GAA) nanosheet transistors, GAA nanowire transistors, or other types of transistors. Further, the memory and the logic circuits may include various contact features (or contacts), vias, and metal lines for connecting the source, drain, and gate electrodes (or terminals) of the transistors to form an integrated circuit.

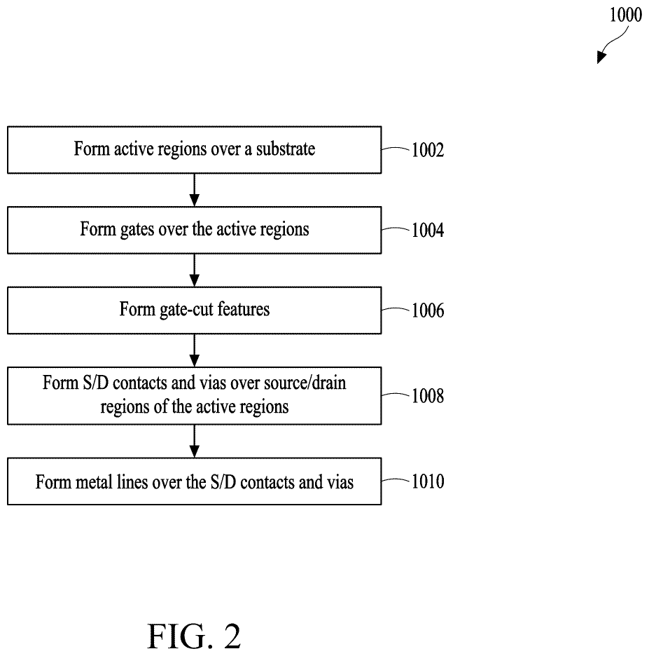

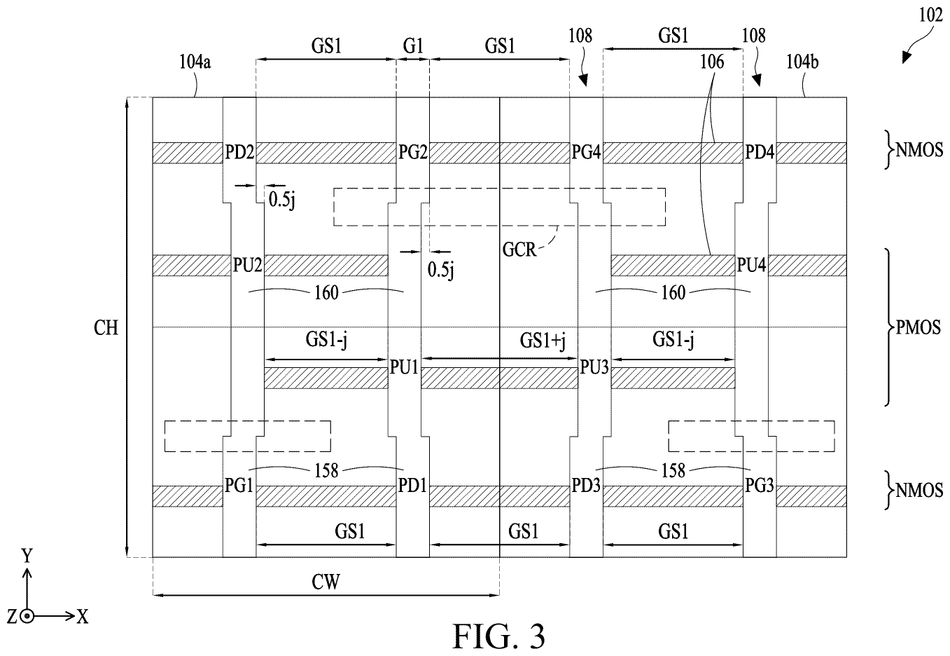

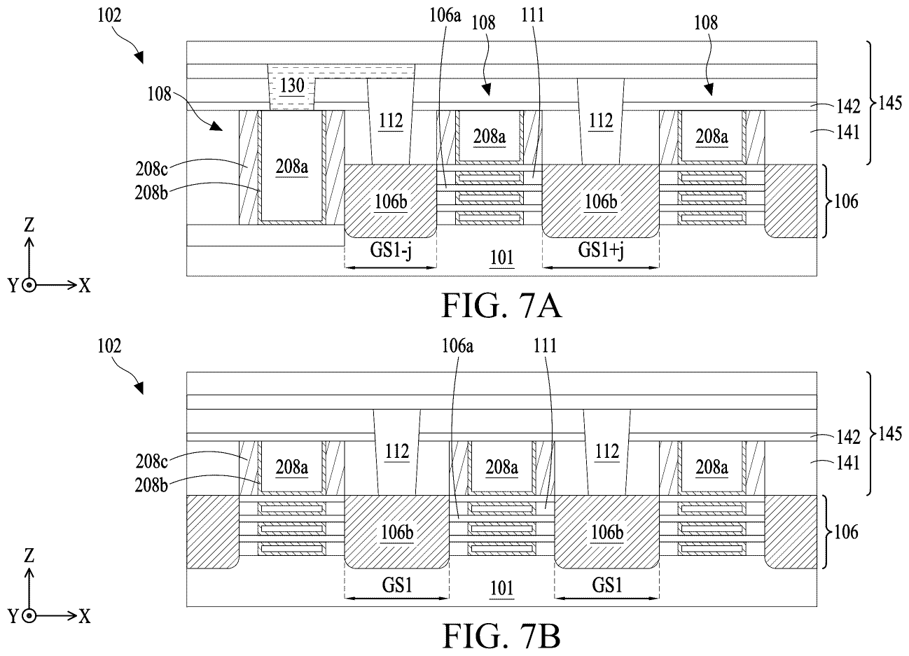

FIG. 2 illustrates a flow chart of a method 1000 to form a memory device 102 having asymmetric gate spacings, in portion or in entirety, according to an embodiment of the present disclosure. The memory device 102 may be generally referred to as a semiconductor device having a corresponding semiconductor layout and structure. The method 1000 is described below with reference to FIGS. 3-6. FIGS. 3-6 illustrate top view device layouts of an SRAM array (as part of the memory device 102) at intermediate stages of fabrication and corresponding to the circuit diagram of FIG. 1. These device layouts have been simplified for the sake of clarity to better understand the inventive concepts of the present disclosure. Some features not shown in FIGS. 3-6 are described with reference to FIGS. 7A-7B, which shows cross-sectional views of the device layouts. Additional features can be added in the memory device 102, and some of the features described below can be replaced, modified, or eliminated in other embodiments of the memory device 102.

Referring now to FIG. 3, the method 1000 at operation 1002 forms active regions 106 over a substrate. The substrate is not shown in FIG. 3 but may correspond to substrate 101 in FIGS. 7A-7B. The substrate may be a silicon (Si) substrate, or a substrate having other semiconductor materials such as germanium (Ge), silicon carbide (SiC), silicon germanium (SiGe), or diamond. The substrate may be doped with a p-type dopant such as boron or an n-type dopant such as arsenic or phosphorus. The active regions 106 protrude above the substrate and may include same or similar materials as the substrate. The active regions 106 may be formed by patterning a base semiconductor layer (or base substrate) to form fin-shaped active regions 106 that protrude above a top surface of the substrate. For example, active regions 106 may be formed by a patterning process that includes lithography and etching. In some embodiments, a lithography process forms a patterned mask layer that covers regions of the base semiconductor layer for forming the active regions 106, and an etching process uses the patterned mask layer as an etch mask to etch exposed portions of the patterned mask layer. The etching process forms recesses that separate and define the active regions 106. The active regions 106 extend lengthwise along the x direction and may also be referred to as fin active regions or semiconductor fins.

As depicted, the active regions 106 may be n-type active regions for forming NMOS transistors or p-type active regions for forming PMOS transistors. N-type active regions may be formed over p-wells (e.g., portions of the substrate doped with p-type dopants such as boron) and p-type active regions may be formed over n-wells (e.g., portions of the substrate doped with n-type dopants such as arsenic or phosphorus). The active regions 106 for forming NMOS transistors may continuously extend across multiple memory cells 104 while the active regions 106 for forming PMOS transistors may be broken up into shorter isolated segments that extends a shorter width. The segmentation of the PMOS active regions 106 may be formed as part of the initial patterning to form all active regions 106. Alternatively, all active regions 106 are first formed to continuously extend across memory cells 104a, then a fin-cut patterning process is performed to form isolation regions that cut through and remove portions of the active regions 106 for forming PMOS transistors. As further described below, the PMOS active regions 106 are to form pull-up transistors, while the NMOS active regions 106 are to form pull-down and pass-gate transistors. As such, the different type active regions 106 may be configured differently depending on design considerations. For example, although not shown, the PMOS active regions 106 may have a smaller width along the y direction than the NMOS active regions 106.

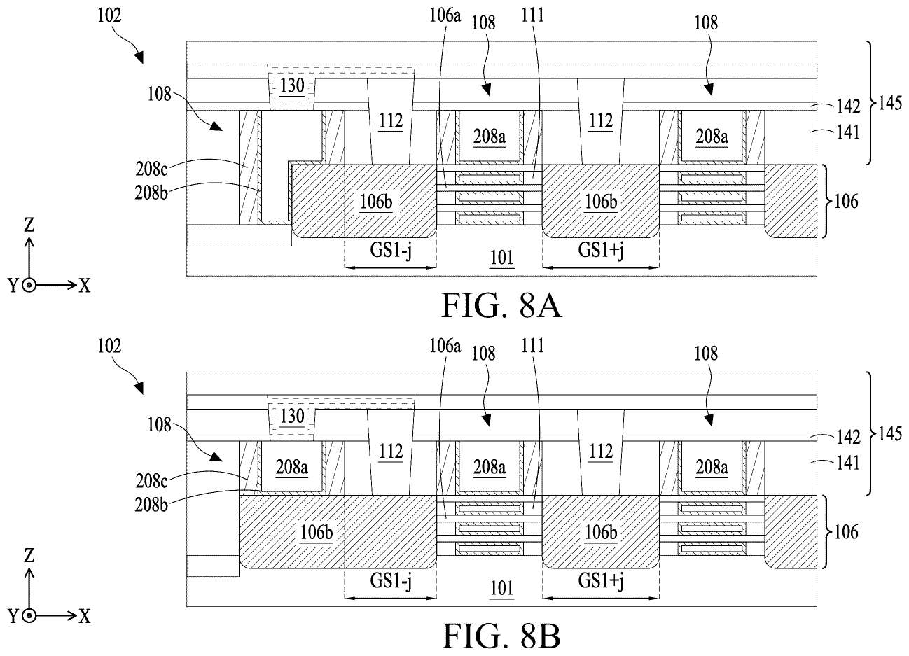

As part of forming active regions 106, the method 1000 further includes forming an isolation structure over the substrate and between the active regions. The isolation structure is not shown in FIG. 3 but may correspond to isolation structure 107 in FIGS. 7A and 8A-8B. The isolation structure may be a shallow trench isolation (STI) layer and provides isolation between adjacent active regions 106 along the y direction. Where there are isolated segments of PMOS active regions 106, the isolation structure may also provide isolation between adjacent PMOS active regions 106 along the x direction.

The isolation structure may be formed by first depositing an isolation layer over the substrate and the active regions 106. The isolation layer lands on a top surface of the substrate, fills in the recesses between the active regions 106, and lands on a top surface of the active regions 106. In other words, the isolation layer is overfilled to surround all exposed surfaces of the active regions 106. The isolation layer may be deposited by any suitable deposition process, and the isolation layer may include silicon oxide, silicon oxynitride, fluorine-doped silicate glass (FSG), a low-k dielectric, combinations thereof, and/or other suitable materials.

Thereafter, the isolation layer may be recessed to form the isolation structure surrounding bottom portions (i.e., lower protruding portions) of the active regions 106. The isolation structure may be formed by first performing a Chemical Mechanical Polish (CMP) to remove excess portions of the isolation layer over top surfaces of the active regions 106. The remaining portions of the isolation layer form isolation regions laterally between active regions 106. Next, the isolation regions are recessed in an etching step, so that exposed fin portions (e.g., upper protruding portions) of the active regions 106 are over the top surfaces of the isolation regions. The resulting isolation regions form the isolation structure. In the present embodiment, the isolation structure is a shallow trench isolation (STI) structure that forms a step-height profile with the active regions 106 (see FIG. 7A isolation structure 107 forming a step height profile with an active region 106). The STI structure may interface an end portion of one or more active regions 106 along the x direction.

Still referring to FIG. 3, the method 1000 at operation 1004 forms gates 108 over channel regions of the active regions 106. The channel regions refer to portions of the active regions 106 directly underneath the gates 108. The gates 108 engages channels of the channel regions. The gates 108 may be formed by first depositing dummy gates (not shown) over channel regions of the active regions 106, then forming source/drain epitaxial features and inner spacers (e.g., source/drain epitaxial features 106b and inner spacers 111 in FIGS. 7A-7B) in source/drain and channel regions of the active regions 106. Thereafter, the dummy gates are replaced with metal gates such as gates 108. The gates 108 engages channels (e.g., channels 106a in FIGS. 7A-7B) in the channel regions. The channels connects adjacent source/drain epitaxial features of the source/drain regions together. The source/drain regions refer to portions of the active regions adjacent the channel regions and not covered by the gates 108. As shown, the gates 108 extend lengthwise in the y direction across one or more channel regions of one or more active regions 106. The gates 108 surround the top and side surfaces of the channel regions. The gates further extends to land on the isolation structure. Each of the gates 108 may include a gate stack and gate spacers over sidewalls of the gate stack. The gate stack and gate spacers are not shown in FIG. 3 but may correspond to gate stack 208a and gate spacers 208c in FIGS. 7A-7B. Further structural details of the gates 108 will be later described with respect to FIGS. 7A-7B.

Of note, the gates 108 are formed continuously along the y direction and may include jogs that cause asymmetric gate spacings along the x direction. The jogs are big enough to cause sufficient spacing separation at specific source/drain regions but small enough to allow the gate to be continuously formed without breaks. Advantageously, the jogs do not impact overall cell layout pattern due to proportional jogs that increase spacing on one side and decrease spacing at another side. Further details of these jogs that cause asymmetric gate spacings are described below with reference to SRAM cell layouts.

As shown in FIG. 3, the memory device 102 includes an SRAM array of two memory cells 104a and 104b (or SRAM cells 104a and 104b). Each memory cell 104 has a cell width CW along the x direction and a cell height CH in the y direction. The SRAM cells 104a and and 104b may correspond to the SRAM cells 104a and 104b in FIG. 1. The SRAM cells 104a and 104b are adjacent to each other in the x direction and mirror each other across a vertical cell boundary between them. Although not shown, the memory device 102 may include additional SRAM cells 104 adjacent to and mirroring the SRAM cells 104a and 104b.

FIG. 3 shows where each of the transistors PU1, PU2, PD1, PD2, PG1, PG2, PU3, PU4, PD3, PD4, PG3, and PG4 will be formed (labeled on the gate 108 of each transistor). How each transistor is connected to each other has already been described with respect to FIG. 2 and will not be repeated here for the sake of brevity.

As shown, the two memory cells 104a and 104b includes the active regions 106 extending along the x direction. The active regions 106 may be configured for planar, fin, or gate-all-around semiconductor structures. In an embodiment, the active regions 106 are fin structures that protrude in the positive z direction from a base substrate, as previously described. Some of the active regions 106 may extend lengthwise across the vertical cell boundaries so that the same active region is shared across SRAM cells 104. The active regions 106 may include n-type active regions 106 for forming pull-down and pass-gate transistors (e.g., NMOS active regions 106 form transistors PD1, PD2, PG1, PG2, PD3, PD4, PG3, and PG4) and p-type active regions 106 for forming pull-up transistors (e.g., PMOS active regions 106 form transistors PU1, PU2, PU3, and PU4). The p-type active regions 106 extends shorter along the x direction than the n-type active regions 106. As shown, the p-type active regions 106 is discontinuous and at most spans a length that is less than a cell width CW of two SRAM cells 104 along the x direction. On the other hand, the n-type active regions 106 may span continuously in the x direction across the whole memory cell area (shown here as spanning across the whole SRAM layout). The gates 108 are disposed over channel regions of the active regions 106 and extend lengthwise in the y direction. Although not shown, some of the gates 108 may extend across the horizontal cell boundaries to span across active regions 106 of different SRAM cells 104 along the y direction.

Each gate 108 has a base portion 158 and a jog portion 160. The gate spacing between adjacent base portions 158 is defined by gate spacing GS1. The gate spacing between the jog portions 160 is different from the gate spacing GS1, resulting in asymmetric gate spacings. For example, the gate spacing between the jog portions may be GS1−j or GS1+j where “j” is a jog distance along the x direction. As shown, to keep a same cell width CW, increasing the gate spacing between a first pair of adjacent jog portions 160 (e.g., by the jog distance j) requires decreasing the gate spacing between a second neighboring pair of adjacent jog portions 160 (e.g., by the jog distance j). Each jog portion 160 shifts its sidewalls from sidewalls of a base portion by 0.5j. This results in a total increase or decrease of gate spacing by the jog distance j for any two adjacent pairs of jog portions 160. Each gate base portion 158 has a gate width G1 along the x direction, which may be a uniform gate width from gate to gate. In this context, “uniform” means an average or substantially same gate width for each gate, even though in real structures the gate may have curved or non-ideal sidewalls due to manufacturing variations. Each cell width CW is defined by two times the gate spacing GS1 plus two times the gate width G1 (i.e., CW=2GS1+2G1). The cell height CH is defined by four times the spacing between active regions 106 along the y direction plus four times a width of the active regions 106 along the y direction (not explicitly labeled).

Gate cut regions GCR are shown at various locations in the memory cells 104a and 104b. The gate cut regions GCR define areas where the gates 108 are to be cut to form separated gates 108 for later-formed transistor devices (e.g., to form isolated gates 108 for pass-gate and pull-up transistors). In the present embodiment, the gate cut regions GCR laterally extends along the x direction at one or more junctions between the base portion 158 and jog portion 160. The gate cut regions may be defined by any suitable patterning process that form patterned masks exposing gate cut regions GCR.

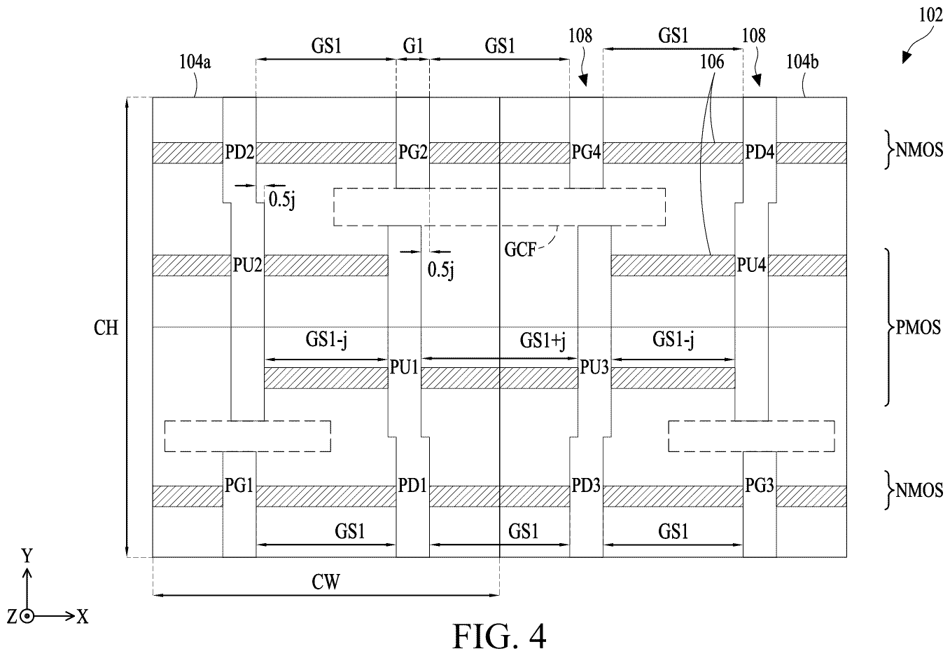

Referring now to FIG. 4, the method 1000 at operation 1006 forms gate-cut features GCF in the gate cut regions GCR. The operation 1004 may include etching through the opening of the patterned masks to remove portions of the gates 108 at the gate cut regions GCR. The etching forms respective trenches that expose the underlying isolation structure (e.g., isolation structure 107 in FIG. 7A). The operation 1004 then fills the trenches with a dielectric material followed by a planarization process (e.g., CMP). The dielectric material may include silicon oxide, silicon oxynitride, fluorine-doped silicate glass (FSG), a low-k dielectric, combinations thereof, and/or other suitable materials. The dielectric material provides isolation between the newly cut gates 108. As shown, the gate-cut features GCF may define shared gates 108 for pull-up and pull-down transistors and pass gates 108 that are only for pass-gate transistors. The gate-cut features GCF interfaces an end portion of the separated gates 108.

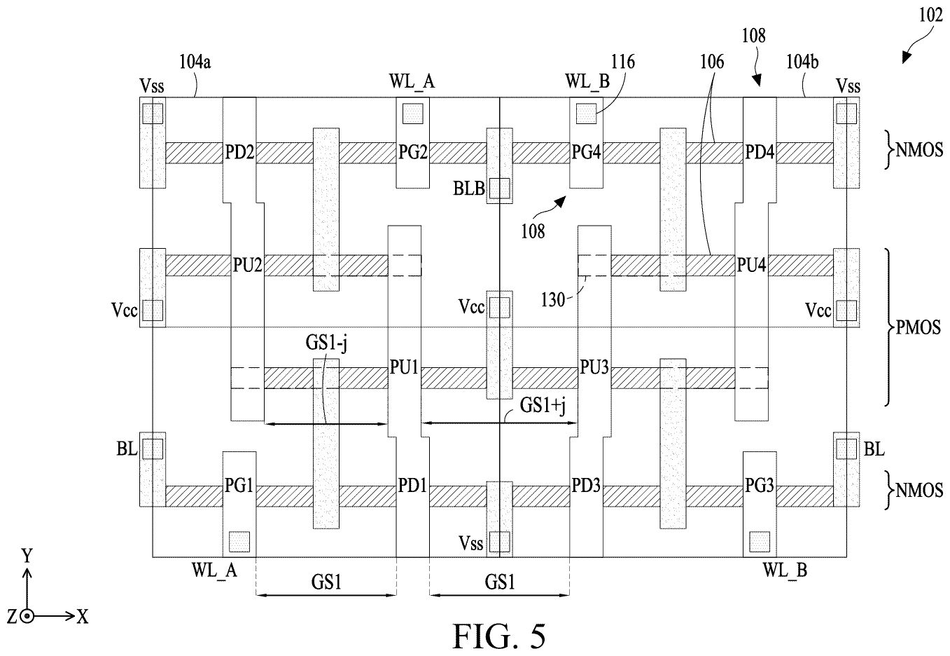

Referring now to FIG. 5, the method 1000 at operation 1008 forms S/D contacts 112 over source/drain (S/D) regions of the active regions 106. The S/D contacts 112 are disposed over and land on S/D epitaxial features of the S/D regions, such as S/D epitaxial features 106b in FIGS. 7A-7B. As shown, some of the S/D contacts 112 are slot contacts that extend in the y direction to couple S/D regions of different transistors together (e.g., a single S/D contact 112 routes the drain regions of transistors PD1, PU1, and PG1 together). The operation 1008 further forms S/D vias 116 over and landing on the S/D contacts. The S/D vias 116 allow the S/D contacts 112 to electrically couple to a higher material layer in the z direction. As part of operation 1004, the method 1000 also forms several butted-contacts 130 for gate-to-drain electrical connections. As shown, the butted-contacts 130 couple various gates 108 to various S/D contacts 112. In an embodiment, the interconnection between the drain (or source) to the gate 108 is achieved by a local interconnect (L1) technology. For example, the local interconnect is formed using the gate material, such as polysilicon, metal, or other conductive material used in gate 108. In this situation, the polysilicon (metal, or other conductive material) is used not only to form the gate stack but also to form the interconnect. More particularly, the gates 108 may be extended to the targeted drain (or source) region and directly lands on the targeted drain (or source) region. In another example, the butted contacts 130 are elongated contacts oriented in the x direction and are formed simultaneously with other contacts in a same procedure that includes dielectric deposition, patterning and metal deposition. The S/D contacts 112, the S/D vias 116, and the butted-contacts 130 may be formed through any suitable patterning and metal deposition process. This may include single or dual damascene processes that separately (or simultaneously) form various layers of embedded conductive features in a dielectric structure (e.g., an intermetal dielectric structure). For example, this may include depositing intermetal dielectric layers over the intermediate structure, forming trenches in the intermetal dielectric layers, then filling the trenches with a conductive material such as Al, W, and/or Cu.

FIG. 5 illustrates where the nodes (or terminals) for Vss, Vcc, BL, WL_A, and WL_B are located at their corresponding S/D contacts 112 and vias 116. These locations and their connections to the underlying gates and source/drains are consistent with the circuit diagram shown in FIG. 1. As shown, it is at the Vcc node where the spacing between gates of pull-up transistors are increased. This is because the gates for the pull-up and pull-down transistors have gate-end portions directly adjacent and in close proximity to p-type active regions 106. The close proximity is to provide landing ground to form the butted-contacts 130. However, this close proximity causes gate bending issues previously described, where the adjacent gates may bend towards each other, decreasing the spacing therebetween. The decreased spacing may adversely affect device performance, causing poorer epitaxial growth and/or gate leakage between the pull-up transistors. As such, the gate spacing at the Vcc node (i.e., the S/D region between adjacent pull-up transistors) is intentionally increased to GS1+j to mitigate the gate bending issues. To keep a consistent cell width CW, the gate spacing at the adjacent interconnect nodes (i.e., the nodes having the butted-contacts 130) is intentionally decreased to GS1−j. In this way, the sum of the spacing between a first pair of jog portions 160 and an adjacent pair of jog portions 160 (i.e., (GS1+j)+(GS1−j)) is equal to the sum of the spacing between a first pair of base portions 158 and an adjacent pair of base portions 158 (i.e., GS1+GS1). Note that the reduced gate spacing GS1−j at the adjacent interconnect nodes does not adversely impact device performance because the edge gates have less impact to S/D epitaxial growth and gate-to-gate leakage. Further, the gate bending may have greater impact towards center S/D regions of the active regions 106 rather than edge S/D regions of the active regions 106.

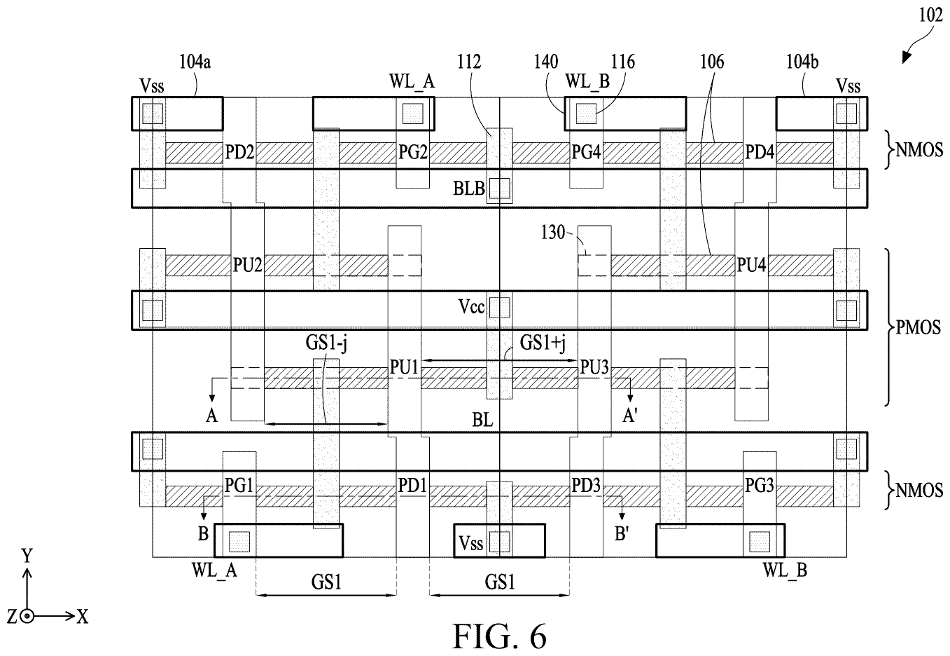

Referring now to FIG. 6, the method 1000 at operation 1010 forms metal lines 140 extending lengthwise along the x direction. The metal lines 140 are disposed over and lands on the vias 116. As shown, some of the metal lines 140 extend across multiple vias 116 to route a same node connection across multiple SRAM cells 104 (e.g., routing together multiple vias 116 for the Vcc node, the BL node, etc.). These metal lines 140 may route S/D features of several pull-up transistors together or route S/D features of several pass-gate transistors together. Some of the metal lines 140 extend only across a single via 116 to route connection from only a single via 116 (e.g., routing a Vss node, a WL_A node, a WL_B node, etc.). The metal lines 140 may be formed through any suitable patterning and metal deposition process. This may include depositing intermetal dielectric layers over the intermediate structure, forming trenches in the intermetal dielectric layers to expose underlying vias 116, then filling the trenches with a conductive material such as Al, W, and/or Cu.

The method 1000 may perform further operations to complete the fabrication of the memory device 102. For example, although not shown, the method 1000 may form additional layers of interconnect vias and metal lines over the metal lines 140 to collectively form an interconnect structure. The interconnect structure electrically couple various devices (for example, p-type transistors and/or n-type GAA transistors of the device 102, other transistors, resistors, capacitors, and/or inductors) and/or components (for example, gate structures and/or epitaxial source/drain features of p-type transistors and/or n-type transistors), such that the various devices and/or components can operate as specified by design requirements of the device 102. The interconnect structure includes a combination of dielectric layers and electrically conductive layers (e.g., metal layers) configured to form various interconnect features. The conductive layers are configured to form vertical interconnect features, such as vias 116 and/or horizontal interconnect features, such as first metal lines 140. Vertical interconnect features typically connect horizontal interconnect features in different layers (or different planes) of the interconnect structure. During operation, the interconnect structure is configured to route signals between the devices and/or the components of the device 102 and/or distribute signals (for example, clock signals, voltage signals, and/or ground signals) to the devices and/or the components of the device 102.

FIGS. 7A-7B illustrate cross-sectional views of an SRAM array of the memory device 102 cut along respective lines A-A′ and B-B′ in FIG. 6. Various features in FIGS. 7A-7B have been described with respect to the method 1000, and some features will not be described again for the sake of brevity.

FIG. 7A illustrates a cross-sectional view of a PMOS active region 106 over a substrate 101 and extending across three gates 108 along the x direction. As shown, the PMOS active region 106 includes S/D epitaxial features 106b and semiconductor channels 106a interposing and connecting the S/D epitaxial features 106b. The PMOS active region 106 is laterally surrounded by an isolation structure 107 that provides isolation between adjacent active regions 106 along the x and y directions (not shown in this view). The PMOS active region 106 protrudes above the isolation structure 107. The isolation structure 107 lands on a top surface of the substrate 101 and is laterally adjacent a protruding portion of the substrate 101 and an end portion of an elongated active region 106. This protruding portion of the substrate 101 may also be referred to as a lower portion of the PMOS active region 106 where the S/D epitaxial features 106b are grown on. As shown, the isolation structure 107 may interface with a sidewall surface of the active region 106, such as a sidewall surface of the S/D epitaxial features 106b at the end portions of the active region 106.

Referring to FIGS. 7A and 7B collectively, the S/D epitaxial features 106b may be formed by etching S/D trenches in S/D regions of the active regions 106, then epitaxially growing the S/D epitaxial features 106b in the S/D trenches. The epitaxially growing may include performing an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of the substrate 101. S/D epitaxial features 106b are doped with n-type dopants and/or p-type dopants. In some embodiments, for p-type GAA transistors (e.g., in FIG. 7A), S/D epitaxial features 106b include silicon germanium or germanium and can be doped with boron, other p-type dopant, or combinations thereof (for example, forming Si:Ge:B epitaxial source/drain features). In some embodiments, for n-type GAA transistors (e.g., in FIG. 7B), S/D epitaxial features 106b include silicon and can be doped with carbon, phosphorous, arsenic, other n-type dopant, or combinations thereof (for example, forming Si:C epitaxial source/drain features, Si:P epitaxial source/drain features, or Si:C:P epitaxial source/drain features).

The epitaxy process may include forming various epitaxial layers of different doping concentrations. For example, the epitaxial features may include a base epitaxial layer (L0) formed over an initially exposed surface of the S/D trenches, including surfaces of the substrate 101 and channels 106a. The L0 epitaxial layer is substantially undoped or includes only a minimal concentration of dopants. The epitaxial features may further include an L1 epitaxial layer, which is formed to have a higher dopant concentration relative to the L0 epitaxial layer. The L1 epitaxial layer may be positioned at regions interfacing the L0 epitaxial layer and along the sidewalls of the inner spacers 111. Additionally, the epitaxial features may include a bulk L2 epitaxial layer, which possesses a dopant concentration greater than that of the L1 epitaxial layer. The L2 epitaxial layer may be surrounded by and embedded within the L1 epitaxial layer. Gate bending caused by close gate landing at the peripheries of active regions 106 can result in suboptimal growth of the L0 epitaxial layer. This is attributed to the reduced bottom spacing between adjacent gates. In the present embodiment, this gate bending issue is present for PMOS active regions 106 and not for NMOS active regions 106. This is because of the gate landings near the edges of the PMOS active regions 106. As such, the jog designs described herein are directed to addressing the challenges associated with the PMOS active regions 106. In alternative embodiments however, such as in a different cell layout, the jog designs may be directed to NMOS active regions 106.

Still referring to FIGS. 7A and 7B, the gates 108 each includes a gate stack 208a and gate spacers 208c adjacent the gate stack. The gate stacks 208a may include gate dielectric layers 208b and a gate electrode disposed on the gate dielectric layers 208b. In some embodiments, the gate dielectric layers 208b includes an interfacial layer and a high-k dielectric layer disposed on the interfacial layer. The gate electrode may include one or more conductive materials, such as a capping layer, a work function metal layer, a blocking layer, a metal fill layer, and/or other proper conductive material layers. The work function layers (if present) may be same or different and may be an n-type work function layer or a p-type work function layer, depending on the types of the corresponding GAA transistors. The gate dielectric layer includes a high-k dielectric material, such as materials having a dielectric constant greater than silicon oxide (k≈3.9). The gate electrodes may be formed by a CVD process or a PVD process that deposits a metal fill layer that fills remaining portions of the gate trenches and over the gate dielectric layers. The metal fill layer includes a suitable conductive material, such as Al, W, and/or Cu. The metal fill layer may additionally or collectively include other metals, metal oxides, metal nitrides, other suitable materials, or combinations thereof. Alternatively, the metal fill layer is formed using another suitable deposition process, such as ALD, CVD, PVD, HDPCVD, MOCVD, RPCVD, PECVD, LPCVD, ALCVD, APCVD, spin coating, plating, other deposition process, or combinations thereof.

Referring to FIG. 7A, the gates 108 that land on the PMOS active region 106 vertically wraps around the channels 106a. Portions of the gate stacks 208a below the topmost channels 106a are laterally surrounded by inner spacers 111 while portions of the gate stacks 208a above the topmost channels 106a are laterally surrounded by the gate spacers 208c. The inner spacers 111 provide isolation between gate and adjacent S/D features. The inner spacers 111 may include same or different dielectric materials as the gate spacers 208c. The dielectric materials may be made of silicon oxide, silicon nitride, silicon oxycarbide, silicon oxycarbonitride, silicon carbonitride, metal nitride, or a suitable dielectric material. The gate spacers 208c and inner spacers 111 may be vertically aligned in the z direction. The gate 108 immediately adjacent the edge of the PMOS active region 106 (or the edge S/D region thereof) lands on the isolation structure 107. This gate does not land on or wrap around channels 106a of the PMOS active region 106. This gate is a gate-end extension portion that acts as landing ground for butted-contact connection. However, other portions of this gate when viewed along the y direction may land on and engage channels 106a of other active regions 106. As shown, the gate-end extension portion has gate spacers 208c and gate stack 208a that continuously extend down to land on the isolation structure 107.

Still referring to FIG. 7A, an intermetal dielectric (IMD) structure 145 is disposed over the PMOS active region 106 and gates 108. The IMD structure 145 may include one or more interlayer dielectric (ILD) layers 141 and one or more etch stop layers 142 that define top and bottom surfaces of various embedded conductive features, such as the top and bottom surfaces of the embedded S/D contacts 112 and butted-contacts 130. The S/D contacts 112 penetrate through one or more ILD layers 141 and one or more etch stop layers 142 to land on the S/D epitaxial features 106b. The butted-contact 130 penetrates through one or more ILD layers 141 and one or more etch stop layers 142 to land on a respective S/D contact 112 and a respective gate-end portion of a gate 108. As shown, the butted-contact 130 provides an interconnect for gate-to-S/D connection. The etch stop layers 142 include different dielectric materials from the ILD layers 141 to provide etchant selectivity. For example, the etch stop layers 142 includes a nitride-based dielectric and the ILD layers 141 includes an oxide-based dielectric. The etch stop layers 142 have a smaller thickness than the ILD layers 141.

FIG. 7B illustrates a cross-sectional view of an NMOS active region 106 over the substrate 101 and extending across three gates 108 along the x direction. FIG. 7B resembles FIG. 7A except that there is no butted-contact 130 and the NMOS active region 106 continuously extends in the x direction without breakage. As such, each of the three gates 108 engages channels 106a of the NMOS active region 106.

Comparing FIG. 7A with FIG. 7B, the gate spacings associated with the PMOS active region 106 are asymmetric, having the gate spacings GS1−j and GS1+j. This asymmetry arises from the inclusion of the jog distance j. Whereas FIG. 7B shows the gate spacings for the NMOS active region 106 are symmetric, each having the gate spacing GS1. These gate spacings refer to the S/D regions between adjacent gates 108. Due to the jog, each of the three gates along the PMOS active region 106 in FIG. 7A is misaligned with each of the three gates along the NMOS active region 106 in FIG. 7B.

FIGS. 8A-8B illustrate cross-sectional views of an SRAM array of the memory device 102 cut along the line A-A′ in FIG. 6, according to additional embodiments of the present disclosure. FIGS. 8A and 8B resemble FIG. 7A, and the similar feature will not be described again for the sake of brevity. Referring back to the embodiment of FIG. 7A, the edge gate 108 has its gate-end portion landing completely on the isolation structure 107 immediately adjacent to the PMOS active region 106. However, in the embodiment of FIG. 8A, the edge gate 108 has its gate-end portion partially landing on the PMOS active region 106 and partially landing on the isolation structure 107. As shown in FIG. 8A, portions of the gate stack 208a and one of the gate spacers 208c may land on a top surface of the edge S/D epitaxial feature 106b. And other portions of the gate stack 208a and another one of the gate spacers 208c may land on the top surface of the isolation structure 107. In this case, the edge S/D epitaxial feature 106b of FIG. 8A may extend a greater length along the x direction than the edge S/D epitaxial feature 106b of FIG. 7A. In the embodiment of FIG. 8B, the edge gate 108 may have its gate-end portion completely landing on the PMOS active region 106. As shown in FIG. 8B, all of the gate stack 208a and the gate spacers 208c may land on a top surface of the edge S/D epitaxial feature 106b. In this case, the edge S/D epitaxial feature 106b of FIG. 8B may extend a greater length along the x direction than the edge S/D epitaxial feature 106b of FIG. 8A.

Still referring to FIGS. 8A-8B, due to the partial or complete landing of the edge gates 108 on the PMOS active region 106, the edge S/D epitaxial features 106b may extend a greater length along the x direction than the spacing GS1−j. This mitigates any impact of having the shorter gate spacing GS1−j, which was necessary in order to compensate for the greater gate spacing at the Vcc node. In other words, the S/D region to form the edge S/D epitaxial features 106b may not be limited by the gate spacing GS1−j. The partial or complete landing of the edge gates 108 do not pose shorting issues because the edge gates 108 are already intended to electrically connect to the underlying S/D epitaxial features 106b, as shown by the overlying butted-contacts 130.

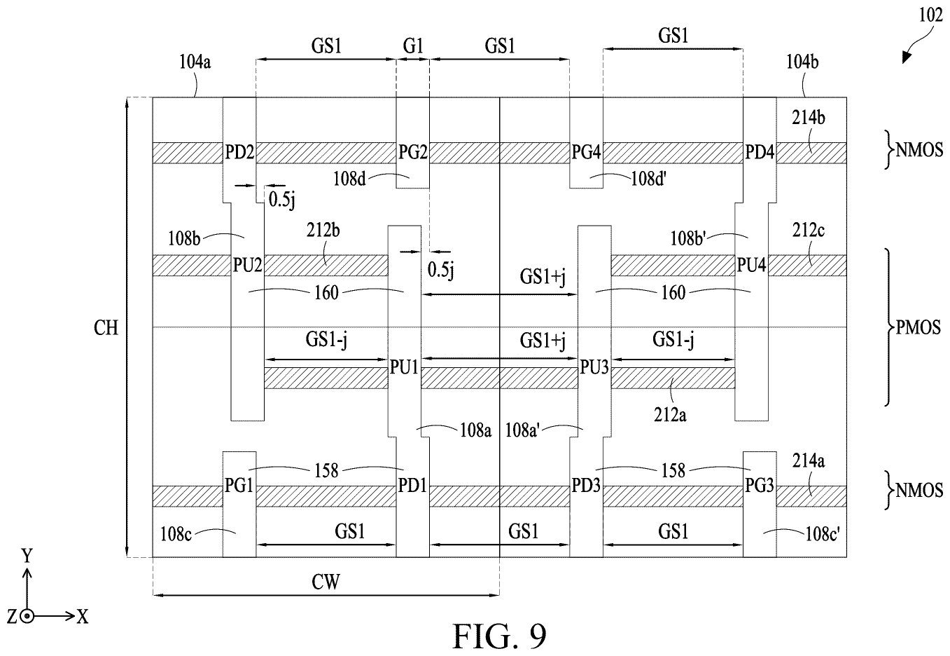

FIGS. 9-12 illustrate top view device layouts of various SRAM arrays having asymmetric gate spacings, according to various embodiments of the present disclosure. Each of the SRAM arrays may be a portion of the memory device 102.

FIG. 9 illustrates the embodiment described with respect to FIGS. 3-6. Some of the features are not described again for the sake of brevity. As shown, the memory device 102 includes SRAM cells 104a and 104b. The SRAM cell 104a includes a first gate 108a, a second gate 108b, a third gate 108c, and a fourth gate 108d. The SRAM cell 104b includes a fifth gate 108a', a sixth gate 108b', a seventh gate 108c', and an eight gate 108d. The first gate 108a engages a channel region of the PMOS active region 212a and a channel region of the NMOS active region 214a to form the PU1 and PD1 transistors. The second gate 108b engages a channel region of the PMOS active region 212b and a channel region of the NMOS active region 214b to form the PU2 and PD2 transistors. The third gate 108c engages a channel region of the NMOS active region 214a to form the PG1 transistor. The fourth gate 108d engages a channel region of the NMOS active region 214b to form the PG2 transistor. The fifth gate 108a′ engages a channel region of the PMOS active region 212a and a channel region of the NMOS active region 214a to form the PU3 and PD3 transistors. The sixth gate 108b′ engages a channel region of the PMOS active region 212c and a channel region of the NMOS active region 214b to form the PU4 and PD4 transistors. The seventh gate 108c′ engages a channel region of the NMOS active region 214a to form the PG3 transistor. The eight gate 108d′ engages a channel region of the NMOS active region 214b to form the PG4 transistor.

Each of the SRAM cells 104a and 104b includes two columns of gates extending in the y direction and four rows of active regions extending along the x direction. The SRAM cell 104a includes a first column having the gates 108b and 108c substantially (or at least partially) aligned along the y direction. The SRAM cell 104a further includes a second column having the gates 108d and 108a substantially (or at least partially) aligned along the y direction. The SRAM cell 104b includes a third column having the gates 108d′ and 108a′ substantially (or at least partially) aligned along the y direction. The SRAM cell 104b further includes a fourth column having the gates 108b′ and 108c′ substantially (or at least partially) aligned along the y direction. The SRAM cell 104a includes a first row having the NMOS active region 214b, a second row having the PMOS active region 212b, a third row having the PMOS active region 212a, and a fourth row having the NMOS active region 214a. The SRAM cell 104b includes the first row having the NMOS active region 214b, the second row having the PMOS active region 212c, the third row having the PMOS active region 212a, and the fourth row having the NMOS active region 214a.

All of the gates 108a-108d and 108a′-108d′ have a base portion 158, while the gates 108a, 108b, 108a′, and 108b′ each further includes a jog portion 160. The jog portions 160 protrudes from sidewalls of respective base portions 158 either towards an adjacent jog portion 160 or away from an adjacent jog portion 160. The jog portions 160 land on and engage channel regions of the pull-up transistors (e.g., PU1-PU4 transistors). Each of the jog portions protrudes from the respective sidewalls by half of a jog distance j. In an embodiment, the jog distance j ranges between about 0.3 nm to about 1 nm. The jog distance j is selected to be large enough to increase gate spacings at desired regions (e.g., greater than 0.3 nm) while small enough to have a transition zone that enables forming a continuous gate (e.g., less than 1 nm). In the present embodiments, the transition zone occurs at a region along the y direction between an NMOS active region and a PMOS active region. Each of the base and jog portions 158 and 160 has a gate width G1 along the x direction. In an embodiment, the gate width G1 ranges between about 2.5 nm to about 3.5 nm. Each of the spacing between adjacent base portions 158 has the gate spacing GS1. In an embodiment, the gate spacing GS1 ranges between about 43 nm to about 47 nm. Each of the spacing between adjacent jog portions 160 has either the gate spacing GS1−j or the gate spacing GS1+j. In an embodiment, a ratio of the jog distance j to the gate width G1 ranges between 0.01 to 0.3, such as between 0.1 to 0.3. The spacing between jog portions 160 of gates 108a and 108a′ is GS1+j. In the present embodiments, this spacing may correspond to a length of a shared S/D region between adjacent pull-up transistors. The spacing between jog portions of the gates 108a and 108b and jog portions of gates 108a′ and 108b′ is GS1−j. In the present embodiments, these spacings correspond to gate spacings adjacent to the GS1+j gate spacing.

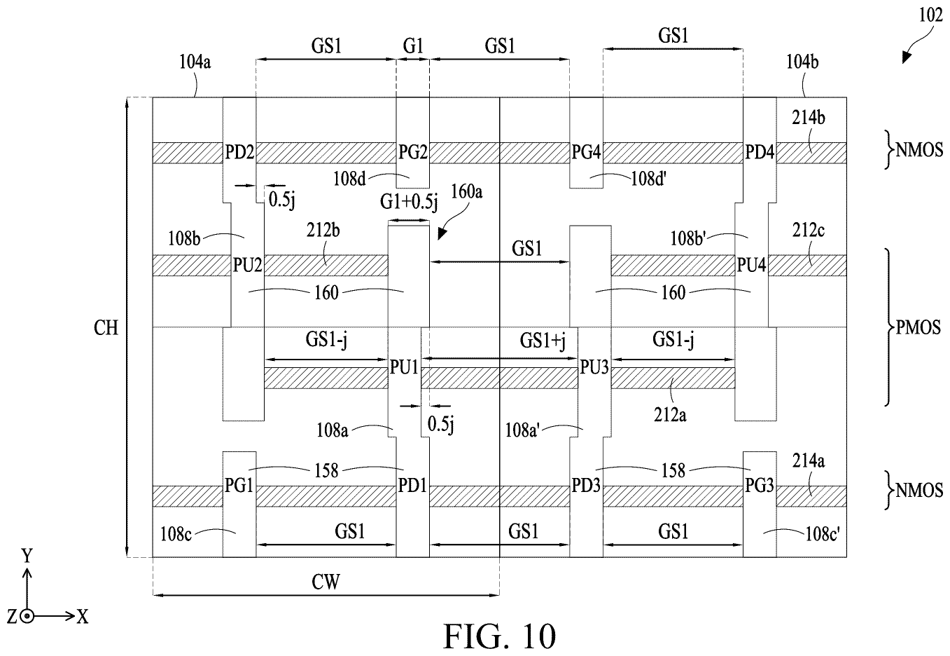

FIG. 10 illustrates another embodiment of an SRAM array having asymmetric gate spacings. FIG. 10 resembles FIG. 9, except that the jog portions 160 further include gate extensions 160a at regions adjacent to the edges of active regions 212a, 212b, and 212c. This further mitigates gate bending and smooths out gate landing. In the present embodiment, the gate extensions 160 a have a width 0.5 j. The gate extensions 160a extend away from edges of the active regions such that a sidewall of the gate extensions 160a aligns with a sidewall of the base portions 158 along the y direction. As such, the jog portions 160 with the gate extensions 160a may have a gate width of G1+0.5 j. The gate extensions 160a may span half a length of the jog portions 160 in the y direction, such as to a middle of the cell boundary along the y direction. With the inclusion of gate extensions 160a, the spacing between jog portions 160 at the edges of the active regions 212b and 212c corresponds to the gate spacing GS1. In contrast, the spacing between jog portions 160 that do not include gate extensions 160a remains unchanged.

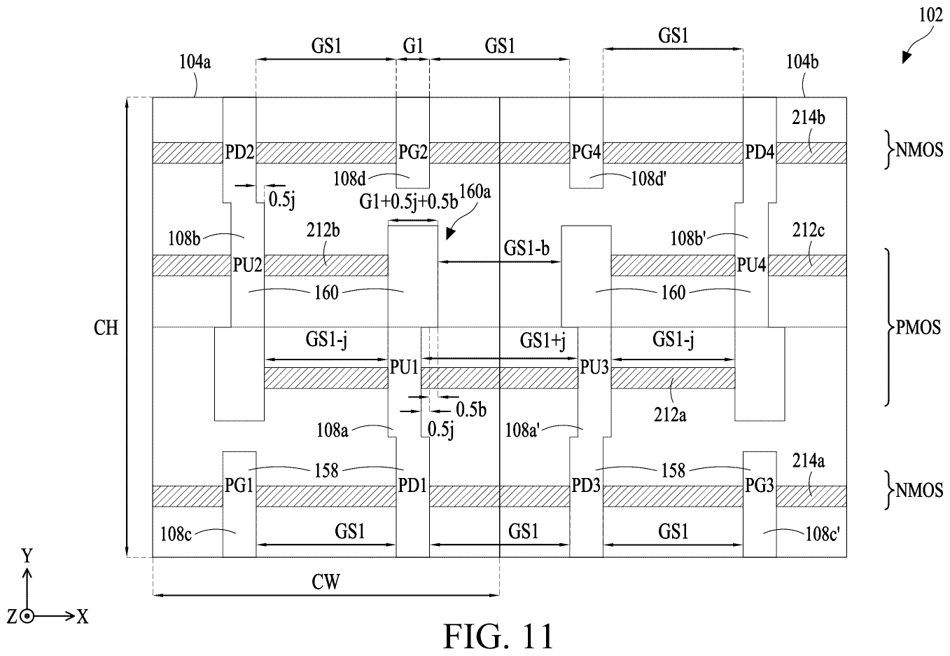

FIG. 11 illustrates another embodiment of an SRAM array having asymmetric gate spacings. FIG. 11 resembles FIG. 10, except that the gate extensions 160a is further increased. In the present embodiment, the gate extensions 160a has a width 0.5j+0.5b, where b may be equal to or less than the jog distance j. In an embodiment, the distance b ranges between about 0.3 nm to about 0.5 nm. In this embodiment, the gate extensions 160a extend away from edges of the active regions such that a sidewall of the gate extensions 160a extends beyond a sidewall of the base portions 158. As such, the jog portions 160 with the gate extensions 160a may have a gate width of G1+0.5 j+0.5 b. The gate extensions 160a may span half a length of the jog portions 160 in the y direction, such as to a middle of the cell boundary along the y direction. With the inclusion of gate extensions 160a, the spacing between jog portions 160 at the edges of the active regions 212b and 212c corresponds to the gate spacing GS1−b. In contrast, the spacing between jog portions 160 that do not include gate extensions 160a remains unchanged. The increased gate extensions 160a provide greater structural integrity to the respective gate base portions 158, thereby further reducing gate bending and improving S/D epitaxial growth window.

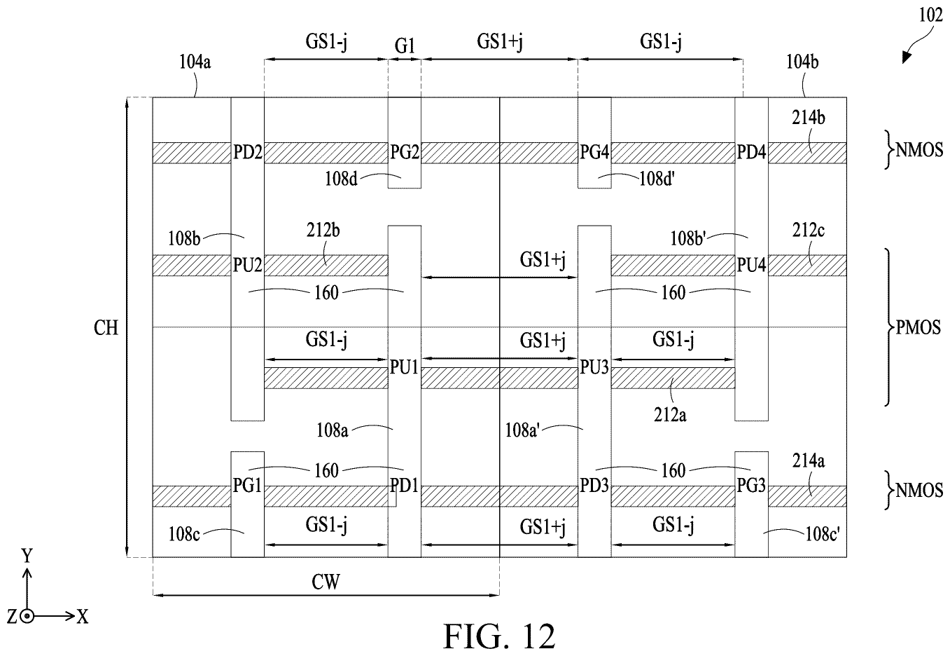

FIG. 12 illustrates another embodiment of an SRAM array having asymmetric gate spacings. FIG. 10 resembles FIG. 9, except that the base portions 158 are now also jog portions 160. In other words, each of the gates 108 are uniformly jogged (in their entirety) along the x direction. In this embodiment, the gate spacing between adjacent pull-down transistors may also be the same as the gate spacing GS1+j between adjacent pull-up transistors. And the gate spacing between pull-down and pass-gate transistors may also be the same as the gate spacing GS1−j between an edge gate and the gate of a pull-up transistor. The uniform jog lowers manufacturing difficulty by avoiding the need to pattern and form transition zones that jog between different gate portions.

Notably, due to the various gate spacings described herein (e.g., GS1, GS1+j, GS1−j, etc.), the S/D epitaxial features 106b formed in these gate spacings may also have corresponding dimensions (e.g., similar or proportional in size). For example, in FIG. 7A, one of the S/D epitaxial features 106b (e.g., formed in the gate spacing GS1−j) may have a smaller width than another S/D epitaxial features 106b (e.g., formed in the gate spacing GS1+j). As such, the asymmetric gate spacings may result in correspondingly asymmetric S/D epitaxial feature sizes. However, in some of the previously described embodiments, certain edge S/D epitaxial features 106b may not be limited by the gate spacings (e.g., see FIGS. 8A and 8B and related description).

Although not limiting, the present disclosure offers advantages for memory device cell layouts. One example advantage is to form asymmetric gate spacings to improve process windows while maintaining consistent cell layouts. Another example advantage is to introduce gate extensions at regions adjacent to the edges of active regions to mitigate gate bending and smooth out gate landing. Another example advantage is to introduce various jog to tune device layout. Another example advantage is to allow gate-end extension portions to land on edges of active regions.

One aspect of the present disclosure pertains to a semiconductor device. The device includes first, second, third, fourth, and fifth active regions extending lengthwise along a first direction, wherein the first and fifth active regions extend completely across a first cell and an adjacent second cell, wherein the second, third, and fourth active regions extend partially across the first and second cells and are disposed between the first and fifth active regions along a second direction different from the first direction; a first gate stack engaging the first and second active regions, the first gate stack extending lengthwise over the first cell along the second direction; a second gate stack engaging the fifth active region, the fifth gate stack extending lengthwise over the first cell along the second direction; a third gate stack engaging the first active region, the third gate stack extending lengthwise over the first cell along the second direction; a fourth gate stack engaging the fourth and fifth active regions, the fourth gate stack extending lengthwise over the first cell along the second direction; a fifth gate stack engaging the first active region, the fifth gate stack extending lengthwise over the second cell along the second direction; and a sixth gate stack engaging the fourth and fifth active regions, the sixth gate stack extending lengthwise over the second cell along the second direction. An isolation dielectric feature interfaces an end portion of one or more active regions of the second, third, and fourth active regions. The fourth gate stack extends between the first and the sixth gate stacks, wherein along the first direction, a spacing between the first gate stack and the fourth gate stack spans a first distance, a spacing between the fourth gate stack and the sixth gate stack spans a second distance, and the second distance is greater than the first distance.

In an embodiment, the second active region extends lengthwise within the first cell and the third active region extends lengthwise within the second cell. The fourth active region extends lengthwise across the first and second cells. The first and the fifth active regions form n-type active regions, and the second, the third, and the fourth active regions form p-type active regions.

In an embodiment, a spacing between the first gate stack and the third gate stack and a spacing between the second gate stack and the fourth gate stack each span a third distance, wherein the third distance is greater than the first distance but smaller than the second distance.

In an embodiment, a spacing between the first gate stack and the third gate stack and a spacing between the second gate stack and the fourth gate stack each span the first distance, wherein a spacing between the third gate stack and the fifth gate stack and a spacing between the fourth gate stack and the sixth gate stack each span the second distance.

In an embodiment, the first gate stack, the fourth gate stack, and the sixth gate stack each includes a base portion and a jog portion, wherein the respective jog portions of the first and fourth gate stacks bend towards each other from their respective base portions to reduce the spacing between the first and the fourth gate stacks by a jog distance, wherein the respective jog portions of the fourth and sixth gate stacks bend away from each other from their respective base portions to increase the spacing between the fourth and the sixth gate stacks by the jog distance.

In a further embodiment, the base portion of the first gate stack engages the first active region and the jog portion of the first gate stack engages the second active region.

In a further embodiment, a spacing between the third gate stack and the fifth gate stack spans a third distance, wherein the first distance equals the third distance minus the jog distance and the second distance equals the third distance plus the jog distance.

In a further embodiment, the first gate stack, the fourth gate stack, and the sixth gate stack each further includes an extension portion, wherein each of the extension portion extends a width of a respective jog portion by half of the jog distance, wherein the extension portions extend from gate-end jog portions that are directly adjacent to edges of one of the second, third, and fourth active regions. In a further embodiment, a spacing between the third gate stack and the fifth gate stack spans a third distance, and a spacing between two adjacent gate-end jog portions also spans the third distance.

In an embodiment, the semiconductor device further includes a first source/drain feature spanning the first distance over one of the active regions; and a second source/drain feature spanning the second distance over the one of the active regions.

Another aspect of the present disclosure pertains to a semiconductor device. The device includes a first cell having: first and second active regions extending lengthwise along a first direction, the second active region extends a greater length than that of the first active region in the first cell; a first gate stack extending along a second direction different from the first direction, the first gate stack engages a first channel region of the first active region and a first channel region of the second active regions; a second gate stack extending along the second direction, the second gate stack engages a second channel region of the second active region; and a third gate stack extending along the second direction, the third gate stack has a gate end portion adjacent a first edge of the first active region. The device includes a second cell having: the first and the second active regions extending lengthwise along the first direction, the second active region extends a greater length than that of the first active region in the second cell; a fourth gate stack extending along the second direction, the fourth gate stack engages a second channel region of the first active region and a third channel region of the second active region; a fifth gate stack extending along the second direction, the fifth gate stack engages a fourth channel region of the second active region; and a sixth gate stack extending along the second direction, the sixth gate stack has a gate end portion adjacent a second edge of the first active region. The first active region between the first gate stack and the third gate stack spans a first distance, the first active region between the first gate stack and the fourth gate stack spans a second distance, and the second distance is greater than the first distance.

In an embodiment, the second active region between the first gate stack and the second gate stack spans a third distance, and the second active region between the first gate stack and the fourth gate stack spans the third distance. The third distance is greater than the first distance but smaller than the second distance. In an embodiment, the first distance equals the third distance minus a jog distance, and the second distance equals the third distance plus the jog distance.

In a further embodiment, the second gate stack has a uniform gate width, and each of the first and second cells has a cell width equal to two times the third distance plus two times the uniform gate width. In a further embodiment, the sum of the first distance and the second distance plus two times the uniform gate width also equals the cell width.

In an embodiment, the second gate stack has a uniform gate width, and the gate end portion of the third gate stack has the uniform gate width.

In an embodiment, the second gate stack has a uniform gate width, and the gate end portion of the third gate stack has a greater width than the uniform gate width. In a further embodiment, the gate end portion of the third gate stack has a sidewall aligned with a sidewall of the second gate stack along the second direction.

Another aspect of the present disclosure pertains to a method of forming a semiconductor device. The method includes forming active regions over a substrate, the active regions extending lengthwise along a first direction; forming gates over channel regions of the active regions, the gates extending lengthwise along a second direction different from the first direction, wherein each gate includes jogs that cause asymmetric gate spacings along the first direction; forming gate-cut features that cut across the gates along the first direction and at one or more junctions at end portions of the jogs; and
forming source/drain contacts and vias over source/drain features of the active regions, wherein the source/drain features have asymmetric widths corresponding to the asymmetric gate spacings.

In an embodiment, the gates having the jogs are formed continuously without breaks.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
first, second, third, fourth, and fifth active regions extending lengthwise along a first direction, wherein the first and fifth active regions extend completely across a first cell and an adjacent second cell, wherein the second, third, and fourth active regions extend partially across the first and second cells and are disposed between the first and fifth active regions along a second direction different from the first direction;
a first gate stack engaging the first and second active regions, the first gate stack extending lengthwise over the first cell along the second direction;
a second gate stack engaging the fifth active region, the fifth gate stack extending lengthwise over the first cell along the second direction;
a third gate stack engaging the first active region, the third gate stack extending lengthwise over the first cell along the second direction;
a fourth gate stack engaging the fourth and fifth active regions, the fourth gate stack extending lengthwise over the first cell along the second direction;
a fifth gate stack engaging the first active region, the fifth gate stack extending lengthwise over the second cell along the second direction; and
a sixth gate stack engaging the fourth and fifth active regions, the sixth gate stack extending lengthwise over the second cell along the second direction,
wherein an isolation dielectric feature interfaces an end portion of one or more active regions of the second, third, and fourth active regions,
wherein the fourth gate stack extends between the first and the sixth gate stacks,
wherein along the first direction, a spacing between the first gate stack and the fourth gate stack spans a first distance, a spacing between the fourth gate stack and the sixth gate stack spans a second distance, and the second distance is greater than the first distance.

2. The semiconductor device of claim 1,
wherein the second active region extends lengthwise within the first cell and the third active region extends lengthwise within the second cell,
wherein the fourth active region extends lengthwise across the first and second cells,
wherein the first and the fifth active regions form n-type active regions, and the second, the third, and the fourth active regions form p-type active regions.

3. The semiconductor device of claim 1,
wherein a spacing between the first gate stack and the third gate stack and a spacing between the second gate stack and the fourth gate stack each span a third distance,
wherein the third distance is greater than the first distance but smaller than the second distance.

4. The semiconductor device of claim 1,
wherein a spacing between the first gate stack and the third gate stack and a spacing between the second gate stack and the fourth gate stack each span the first distance,
wherein a spacing between the third gate stack and the fifth gate stack and a spacing between the fourth gate stack and the sixth gate stack each span the second distance.

5. The semiconductor device of claim 1,
wherein the first gate stack, the fourth gate stack, and the sixth gate stack each includes a base portion and a jog portion,
wherein the respective jog portions of the first and fourth gate stacks bend towards each other from their respective base portions to reduce the spacing between the first and the fourth gate stacks by a jog distance,
wherein the respective jog portions of the fourth and sixth gate stacks bend away from each other from their respective base portions to increase the spacing between the fourth and the sixth gate stacks by the jog distance.

6. The semiconductor device of claim 5,
wherein the base portion of the first gate stack engages the first active region and the jog portion of the first gate stack engages the second active region.

7. The semiconductor device of claim 5,
wherein a spacing between the third gate stack and the fifth gate stack spans a third distance, wherein the first distance equals the third distance minus the jog distance and the second distance equals the third distance plus the jog distance.

8. The semiconductor device of claim 5,
wherein the first gate stack, the fourth gate stack, and the sixth gate stack each further includes an extension portion, wherein each of the extension portion extends a width of a respective jog portion by half of the jog distance,
wherein the extension portions extend from gate-end jog portions that are directly adjacent to edges of one of the second, third, and fourth active regions.

9. The semiconductor device of claim 8,
wherein a spacing between the third gate stack and the fifth gate stack spans a third distance, and a spacing between two adjacent gate-end jog portions also spans the third distance.

10. The semiconductor device of claim 1, further comprising:
a first source/drain feature spanning the first distance over one of the active regions; and
a second source/drain feature spanning the second distance over the one of the active regions.

11. A semiconductor device comprising:
a first cell having:
first and second active regions extending lengthwise along a first direction, the second active region extends a greater length than that of the first active region in the first cell;
a first gate stack extending along a second direction different from the first direction, the first gate stack engages a first channel region of the first active region and a first channel region of the second active regions;
a second gate stack extending along the second direction, the second gate stack engages a second channel region of the second active region; and
a third gate stack extending along the second direction, the third gate stack has a gate end portion adjacent a first edge of the first active region; and
a second cell having:
the first and the second active regions extending lengthwise along the first direction, the second active region extends a greater length than that of the first active region in the second cell;
a fourth gate stack extending along the second direction, the fourth gate stack engages a second channel region of the first active region and a third channel region of the second active region;
a fifth gate stack extending along the second direction, the fifth gate stack engages a fourth channel region of the second active region; and
a sixth gate stack extending along the second direction, the sixth gate stack has a gate end portion adjacent a second edge of the first active region,
wherein the first active region between the first gate stack and the third gate stack spans a first distance, the first active region between the first gate stack and the fourth gate stack spans a second distance, and the second distance is greater than the first distance.

12. The semiconductor device of claim 11,
wherein the second active region between the first gate stack and the second gate stack spans a third distance, and the second active region between the first gate stack and the fourth gate stack spans the third distance,
wherein the third distance is greater than the first distance but smaller than the second distance.

13. The semiconductor device of claim 12,
wherein the first distance equals the third distance minus a jog distance, and the second distance equals the third distance plus the jog distance.

14. The semiconductor device of claim 12, wherein the second gate stack has a uniform gate width, and each of the first and second cells has a cell width equal to two times the third distance plus two times the uniform gate width.

15. The semiconductor device of claim 14, wherein the sum of the first distance and the second distance plus two times the uniform gate width also equals the cell width.

16. The semiconductor device of claim 11, wherein the second gate stack has a uniform gate width, and the gate end portion of the third gate stack has the uniform gate width.

17. The semiconductor device of claim 11, wherein the second gate stack has a uniform gate width, and the gate end portion of the third gate stack has a greater width than the uniform gate width.

18. The semiconductor device of claim 17, wherein the gate end portion of the third gate stack has a sidewall aligned with a sidewall of the second gate stack along the second direction.

19. A method of forming a semiconductor, comprising:
forming active regions over a substrate, the active regions extending lengthwise along a first direction;
forming gates over channel regions of the active regions, the gates extending lengthwise along a second direction different from the first direction, wherein each gate includes jogs that cause asymmetric gate spacings along the first direction;
forming gate-cut features that cut across the gates along the first direction and at one or more junctions at end portions of the jogs; and
forming source/drain contacts and vias over source/drain features of the active regions, wherein the source/drain features have asymmetric widths corresponding to the asymmetric gate spacings.

20. The method of claim 19, wherein the gates having the jogs are formed continuously without breaks.
